(19) United States
(12) Patent Application Publication
(10) Pub. No.: US 2008/0203536 A1
(43) Pub. Date: Aug. 28, 2008

(54) BIPOLAR TRANSISTOR USING SELECTIVE DIELECTRIC DEPOSITION AND METHODS FOR FABRICATION THEREOF

(75) Inventors: Toshiharu Furukawa, Essex Junction, VT (US); David V. Horak, Essex Junction, VT (US); Benjamin T. Voegeli, Burlington, VT (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 11/679,971

(22) Filed: Feb. 28, 2007

(51) Int. Cl. H01L 29/73; H01L 21/331

(52) U.S. Cl. 257/586; 438/369; 257/E29.174; 257/E21.37

(57) ABSTRACT

A bipolar transistor structure and related methods for fabrication thereof are provided. A vertical spacer layer is selectively deposited after implanting an extrinsic base region into a semiconductor substrate while using an ion implantation mask located upon a screen dielectric layer located upon the semiconductor substrate. A portion of the ion implantation mask may remain embedded and aligned within a sidewall of an aperture within the vertical spacer layer. The selective deposition of the vertical spacer layer allows for a reduced thermal budget and reduced process complexity when fabricating the bipolar transistor.

### BACKGROUND

1. Field of the Invention

The invention relates generally to bipolar transistors. More particularly, the invention relates to bipolar transistors with enhanced performance.

2. Description of the Related Art

In addition to field effect transistors, resistors, diodes and capacitors, semiconductor circuits also often include bipolar transistors. Bipolar transistors are desirable within semiconductor circuits insofar as bipolar transistors may often be fabricated to provide semiconductor circuits with enhanced speed.

Although bipolar transistors provide performance advantages within semiconductor circuits, they are not entirely without problems. Bipolar transistors are generally more difficult to fabricate, thus bipolar transistors typically require a more complex manufacturing process in comparison with field effect transistors. Given the complexity of such a manufacturing process, bipolar transistors often require an enhanced thermal budget in comparison with field effect transistor manufacturing processes. An enhanced thermal budget, in turn, often leads to an enhanced probability for detrimental effects, such as, for example, undesirable dopant diffusion effects.

Of the possible methods for fabricating bipolar transistors, self-aligned methods are generally desirable. Self-aligned methods for fabricating bipolar transistors are generally characterized by alignment of an emitter region to a base region absent the use of a photolithographic process that provides a photolithographic offset. Self-aligned bipolar transistors enjoy performance advantages in comparison with bipolar transistors that are fabricated using non-self-aligned methods. In particular, self-aligned bipolar transistors typically have higher oscillation frequencies, reduced parasitic base resistance and reduced noise in comparison with bipolar transistors that are fabricated using non-self-aligned methods.

Self-aligned bipolar transistor structures and methods for fabrication thereof are known in the semiconductor fabrication art.

For example, Okita, in U.S. Pat. No. 5,234,844, teaches a self-aligned bipolar transistor structure and method for fabrication thereof for use in an ultrahigh speed integrated circuit. Within this prior art reference, the self-aligned bipolar transistor structure has a substantially coaxial symmetric structure.

In addition, Inoue et al., in “Self-Aligned Complementary Bipolar Transistors Fabricated with a Selective-Oxidation Mask,” IEEE Trans. on Electron Devices, Vol. 34(10), 1987, pp. 2146-52 teaches a self-aligned bipolar transistor that uses a 2-μm epitaxial layer and a non-LOCOS trench isolation. Within this prior art reference, active base and emitter regions are formed by ion implantation through a silicon nitride layer.

Desirable are additional self-aligned bipolar transistor structures and methods for fabrication thereof that provide self-aligned bipolar transistors with enhanced performance and ease of manufacturing.

### SUMMARY OF THE INVENTION

The invention provides a semiconductor structure comprising a self-aligned bipolar transistor, and methods for fabricating the semiconductor structure.

A semiconductor structure in accordance with the invention includes a semiconductor substrate that includes a collector region and an intrinsic base surface region located above and contacting the collector region. The semiconductor structure also includes a vertical spacer layer located above the semiconductor substrate. The vertical spacer layer has an aperture therein aligned above the intrinsic base surface region. The aperture has a horizontal spacer layer located embedded within and aligned within a sidewall of the aperture. The semiconductor structure also includes an emitter layer located within the aperture and contacting the intrinsic base surface region.

A method for fabricating a semiconductor structure in accordance with the invention includes implanting an extrinsic base region located laterally connected to an intrinsic base surface region within a semiconductor substrate. The implantation is performed with an ion implantation mask layer disposed on a screen dielectric layer disposed on the semiconductor substrate. The semiconductor substrate includes the intrinsic base surface region located beneath the ion implantation mask layer and a collector region located beneath the intrinsic base surface region. This method also includes selectively depositing a vertical spacer layer upon the screen dielectric layer adjoining the ion implantation mask layer after implanting the extrinsic base region. This method also includes stripping the ion implantation mask layer from the screen dielectric layer to yield an aperture within the vertical spacer layer. The screen dielectric layer is exposed at the base of the aperture. This method also includes removing the screen dielectric layer at the base of the aperture. Finally, this method includes forming an emitter layer into the aperture and contacting the intrinsic base surface region.

Another method for fabricating a semiconductor structure includes implanting, while using an ion implantation mask layer disposed upon a screen dielectric layer which is located upon a semiconductor substrate having an intrinsic base surface region located beneath the ion implantation mask layer and a collector region disposed beneath the intrinsic base surface region, an extrinsic base region located laterally connected to the intrinsic base region. This other method also includes selectively growing a vertical spacer layer upon the screen dielectric layer and encroaching upon the top surface of the adjoining ion implantation mask layer after implanting the extrinsic base region. This other method also includes etching the ion implantation mask layer from the screen dielectric layer to yield an aperture within the vertical spacer layer. The screen dielectric layer is exposed at the base of the aperture, and a horizontal spacer layer is located embedded within and aligned with a sidewall of the aperture. This other method also includes removing the screen dielectric layer at the base of the aperture. This other method also includes forming an emitter layer into the aperture and contacting the intrinsic base surface region.

### BRIEF DESCRIPTION OF THE DRAWINGS

The objects, features and advantages of the invention are understood within the context of the Description of the Preferred Embodiments, as set forth below. The Description of the Preferred Embodiments is understood within the context of the accompanying drawings, that form a material part of this disclosure, wherein:

FIG. 1 to FIG. 8 show a series of schematic cross-sectional diagrams illustrating the results of progressive stages in fabricating a semiconductor structure comprising a bipolar transistor in accordance with an embodiment of the invention.

FIG. 9 to FIG. 15 show a series of schematic cross-sectional diagrams illustrating the results of progressive stages in fabricating a semiconductor structure comprising a bipolar transistor in accordance with another embodiment of the invention.

### DESCRIPTION OF THE PREFERRED EMBODIMENTS

The invention, which comprises a semiconductor structure comprising a bipolar transistor structure and methods for fabrication thereof, is described in further detail below within the context of the drawings described above. The drawings are intended for illustrative purposes only, and as such are not necessarily drawn to scale.

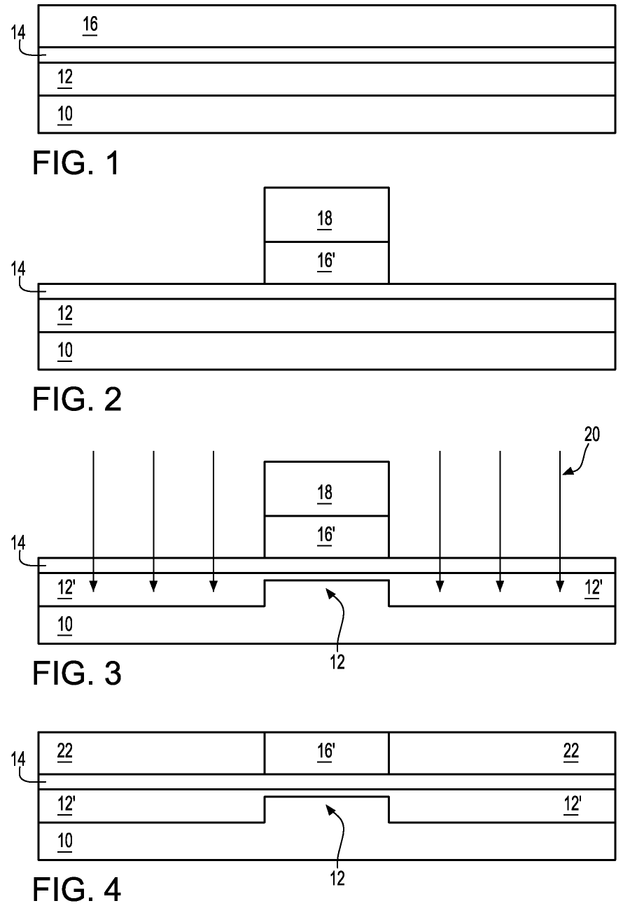

FIG. 1 to FIG. 8 show a series of schematic cross-sectional diagrams illustrating the results of progressive stages in fabricating a semiconductor structure comprising a bipolar transistor in accordance with an embodiment of the invention. This embodiment comprises a first embodiment of the invention.

FIG. 1 shows a semiconductor substrate 10 having an epitaxial intrinsic base region 12 located as a surface layer upon the semiconductor substrate 10. The structure shown in FIG. 1 also includes a screen dielectric layer 14 located upon the intrinsic base region 12 and a hard mask layer 16 located upon the screen dielectric layer 14.

Each of the foregoing semiconductor substrate 10 and layers 12/14/16 located thereupon or thereover may comprise materials and have dimensions that are conventional in the semiconductor fabrication art. Each of the foregoing semiconductor substrate 10 and layers 12/14/16 located thereupon or thereover may be formed using methods that are conventional in the semiconductor fabrication art.

The semiconductor substrate 10 comprises a semiconductor material. Non-limiting examples of semiconductor materials include silicon, germanium, silicon-germanium alloy, silicon carbide, silicon-germanium carbide alloy and compound semiconductor materials. Non-limiting examples of compound semiconductor materials include gallium arsenide, indium arsenide and indium phosphide semiconductor materials. Typically, the semiconductor substrate 10 comprises a silicon semiconductor material. Typically, the silicon semiconductor material has a thickness from about 1 to about 3 mils.

The semiconductor substrate 10 may comprise a bulk semiconductor material. In the alternative, the semiconductor substrate 10 may comprise a semiconductor-on-insulator substrate or a hybrid orientation substrate. A semiconductor-on-insulator substrate comprises a base semiconductor substrate, a buried dielectric layer located thereupon and a surface semiconductor layer located further thereupon. A hybrid orientation substrate comprises multiple regions of different crystallographic orientations. Semiconductor-on-insulator substrates and hybrid orientation substrates may be formed using any of several methods. Non-limiting examples include laminating methods, layer transfer methods and separation by implantation of oxygen methods.

The semiconductor substrate 10 comprises in part a collector region within a bipolar transistor desired to be fabricated using the semiconductor structure whose schematic cross-sectional diagram is illustrated in FIG. 1. Thus, the semiconductor substrate 10 has a first polarity. Typically, the semiconductor substrate 10 has a dopant concentration from about 10¹⁵ to about 10²² dopant atoms per cubic centimeter. A bipolar transistor fabricated in accordance with the invention may have either a p-n-p doping scheme or an n-p-n doping scheme.

The intrinsic base region 12 has an epitaxial thickness of about 50 to about 3000 angstroms upon the semiconductor substrate 10. The intrinsic base region 12 also has a different or an opposite dopant polarity as compared to that of the semiconductor substrate 10 that serves as a collector region. An epitaxial chemical vapor deposition method is used for forming the intrinsic base region 12. The intrinsic base region 12 may comprise a different semiconductor material from the semiconductor material from which is comprised the semiconductor substrate 10. The intrinsic base region 12 may comprise a semiconductor material selected from the same group of semiconductor materials that are listed for the semiconductor substrate 10. Typically and preferably, the intrinsic base region 12 comprises a silicon-germanium alloy semiconductor material when the semiconductor substrate 10 comprises a silicon semiconductor material.

The screen dielectric layer 14 comprises a dielectric material. Non-limiting examples of suitable dielectric materials include oxides, nitrides and oxynitrides of silicon. Oxides, nitrides and oxynitrides of other elements are not excluded. The dielectric material may be formed using any of several methods. Non-limiting examples include thermal or plasma oxidation or nitridation methods, chemical vapor deposition methods and physical vapor deposition methods. Typically, the screen dielectric layer 14 comprises a thermal silicon oxide dielectric material that has a thickness from about 50 to about 500 angstroms upon the intrinsic base region 12.

The hard mask layer 16 (a portion of which eventually serves as an ion implantation mask layer) comprises a hard mask material. Non-limiting examples of hard mask materials include oxides, nitrides and oxynitrides of silicon. Similarly with the screen dielectric layer, oxides, nitrides and oxynitrides of other elements are not excluded. Typically, the hard mask layer 16 and the screen dielectric layer 14 will comprise different dielectric materials in order to provide desired etch selectivity when subsequently etching the hard mask layer 16 with respect to the screen dielectric layer 14. Thus, the hard mask layer 16 typically comprises a silicon nitride hard mask material or a silicon oxynitride hard mask material, when the screen dielectric layer 14 comprises a silicon oxide material. The hard mask material may in general be deposited using methods and materials analogous or equivalent to the methods and materials used for forming the dielectric material from which is comprised the screen dielectric layer 14. The hard mask layer 16 typically has a thickness from about 500 to about 2000 angstroms upon the screen dielectric layer 14.

FIG. 2 shows a photoresist layer 18 located upon a hard mask layer 16′. The hard mask layer 16′ (which also comprises an ion implantation mask layer) results from patterning of the hard mask layer 16 while using the photoresist layer 18 as an etch mask. The foregoing patterning may be effected while using any of several etch methods. Non-limiting examples include wet chemical etch methods and dry plasma etch methods. Dry plasma etch methods are generally more common insofar as they provide anisotropic etch methods that yield nominally straight sidewalls to the hard mask layer 16′. Certain wet chemical etch methods may also be used. When the hard mask layer 16′ comprises a silicon nitride material, a plasma etch method will typically comprise a fluorine containing etchant gas composition for etching the hard mask layer 16 to yield the hard mask layer 16′.

The photoresist layer 18 may comprise any of several photoresist materials. Non-limiting examples include positive photoresist materials, negative photoresist materials and hybrid photoresist materials. Typically, the photoresist layer 18 has a thickness from about 3000 to about 10000 angstroms. Typically, the photoresist layer 18 results from spin coating, photoexposure and development methods that are otherwise generally conventional in the semiconductor fabrication art.

FIG. 3 shows the results of implanting the semiconductor substrate 10 through the screen dielectric layer 14, while using the hard mask layer 16′ and (optionally) the photoresist layer 18 as an ion implantation mask, to form extrinsic base regions 12′ that connect with and are laterally separated by the intrinsic base region 12. The implantation uses a dose of dopant ions 20. The dopant ions 20 are provided at a dose from about 10¹⁴ to about 10¹⁶ dopant ions per square centimeter and an ion implantation energy from about 10 to about 100 KeV. The foregoing ion implantation conditions provide the extrinsic base region 12′ to a depth from about 1000 to about 5000 angstroms within the semiconductor substrate 10, while laterally connecting with and incorporating portions of the intrinsic base region 12.

FIG. 4 first shows the results of stripping the photoresist layer 18 from the hard mask layer 16′. The photoresist layer 18 may be stripped from the hard mask layer 16′ while using methods and materials that are conventional in the semiconductor fabrication art. Non-limiting examples include wet chemical methods, dry plasma methods and aggregate methods and materials thereof.

FIG. 4 also shows vertical spacer layers 22 (i.e., a plurality is cross-section, but intended as generally representative of as single layer in plan-view). Within the embodiment, the vertical spacer layers 22 comprise a dielectric material. The dielectric material is selectively deposited to provide vertical spacer layers 22 of height nominally equivalent to the height of the hard mask layer 16′. Non-limiting examples of selectively deposited dielectric materials include oxides, nitrides and oxynitrides of silicon. Again, oxides, nitrides and oxynitrides of other elements are not excluded. Commonly, a selectively deposited silicon oxide material is deposited upon the screen dielectric layer 14 that comprises a silicon oxide material.

Selective dielectric deposition methods may commonly include, but are not limited to, liquid phase deposition methods. The methods may utilize a specific catalytic activity of an active surface for purposes of selective deposition upon that surface.

Within the context of the instant embodiment for selectively depositing a silicon oxide vertical spacer layer 22 upon a silicon oxide screen dielectric layer 14, a particular liquid phase deposition method uses a supersaturated solution of hydrofluorosilicic acid (i.e., H₃SiF₆) as a silicon oxide deposition source. The supersaturated solution of hydrofluorosilicic acid may be prepared by addition of aluminum or boric acid (i.e., H₃BO₃) to a saturated solution of hydrofluorosilicic acid until saturation of the boric acid. The saturated solution of hydrofluorosilicic acid may be prepared by addition of silicon dioxide (i.e., SiO₂) to hydrofluoric acid (i.e., HF) until saturation of the silicon dioxide. Hydrolysis of the foregoing solutions may lead to a fluorinated deposited silicon oxide rather than a deposited silicon oxide. A fluorine content of up to about 10 atomic percent is contemplated within such a fluorinated deposited silicon oxide. Fluorinated deposited silicon oxide layers may also have superior electrical properties due to generally lower dielectric constants (i.e., about 2.5 to about 3.5) in comparison with non-fluorinated deposited silicon oxides (i.e., about 3.5 to about 4.0).

The supersaturated solution of hydrofluorosilicic acid may be prepared, and the liquid phase selective deposition may be undertaken, at a temperature from about 0° to about 35° C. The selective deposition may also be undertaken at a higher temperature while using simple immersion of an appropriately fabricated substrate in accordance with the embodiment into a supersaturated solution of hydrofluorosilicic acid (or a hydrolyzed supersaturated solution of hydrofluorosilicic acid). Additional details and description of a particular liquid phase epitaxy method may be found in U.S. Pat. No. 6,995,065, the disclosure of which is incorporated herein fully by reference.

Use of the foregoing selective deposition method for forming the vertical spacer layers 22 is desirable insofar as the vertical spacer layers 22 may be deposited at a generally lower temperature (i.e., in a range from about 0° to about 35° C.) that allows for a more limited thermal exposure and thus a more limited thermal budget when fabricating the semiconductor structure whose schematic plan-view diagram is illustrated in FIG. 4.

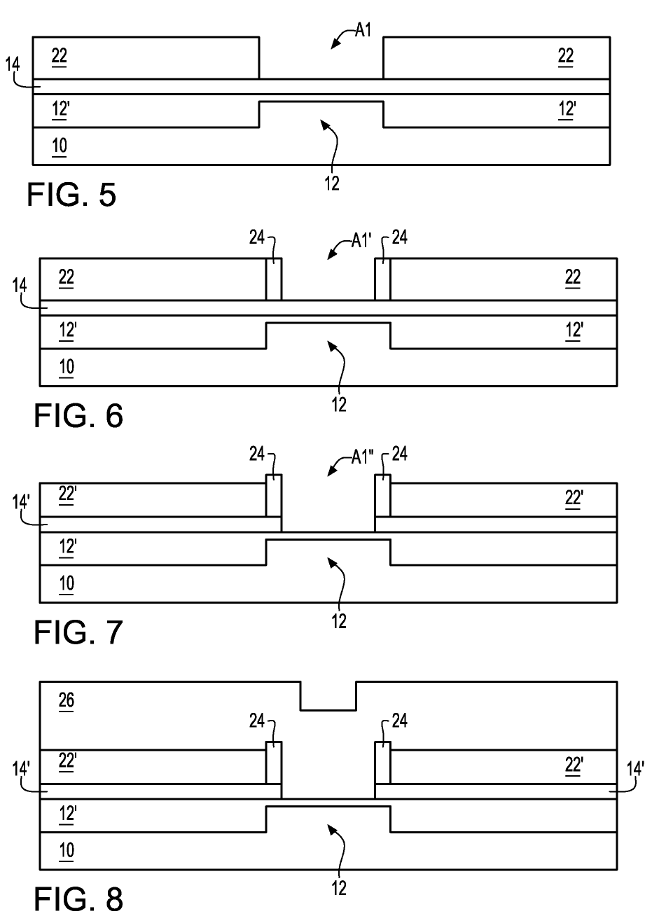

FIG. 5 shows the results of stripping the hard mask layer 16′ from the adjoining vertical spacer layers 22 and the underlying screen dielectric layer 14 to form an aperture A1 within the vertical spacer layer 22. The hard mask layer 16′ may be selectively stripped using methods and materials that are conventional in the semiconductor fabrication art. Typically, the hard mask layer 16′ (when comprising a silicon nitride material) may be selectively stripped with respect to the vertical spacer layers 22 and the underlying screen dielectric layer 14 (when comprising silicon oxide materials) while using an aqueous phosphoric acid etchant at an elevated temperature. Other selective etching methods and materials may alternatively also be used within the context of alternative dielectric materials compositions and selections. In particular, hydrofluoric acid materials are generally specific etchants within the context of silicon oxide materials with respect to silicon nitride materials. Material specific plasma etch methods are also known.

FIG. 6 shows the results of forming horizontal spacer layers 24 (illustrated as a plurality in cross-section, but intended as a single annular spacer layer in plan-view) adjoining sidewalls of the vertical spacer layers 22 (which are also illustrated as a plurality in cross-section, but intended as a single annular spacer layer in plan-view). The presence of the horizontal spacer layers 24 forms an aperture A1′ from the aperture A1. Horizontal spacer layers 24 of necessity comprise a spacer material of a composition that is different than the vertical spacer layers 22. Typically, but not exclusively, the horizontal spacer layers 24 comprises a nitride spacer material. The horizontal spacer layers 24 are formed using a generally conventional blanket layer deposition and an anisotropic etchback method. An appropriate nitride blanket layer may be deposited using methods including, but not limited to: thermal or plasma nitridation methods, chemical vapor deposition methods and physical vapor deposition methods. The anisotropic etchback method typically comprises a plasma etch method.

FIG. 7 shows the results of etching the screen dielectric layer 14 at the base of the aperture A1′ to form an aperture A1″ bounded in part by screen dielectric layer 14′. Exposed at the bottom of the aperture A1″ is the intrinsic base region 12 as a surface region. When the screen dielectric layer 14 and the vertical spacer layers 22 are formed of a similar dielectric material (i.e., an oxide dielectric material in the instant embodiment) they may both be etched using a single etchant to form the aperture A1″ along with vertical spacer layers 22′ and screen dielectric layers 14′.

FIG. 8 shows an emitter layer 26 located within the aperture A1″ that is illustrated in FIG. 7, and contacting an exposed surface region portion of the intrinsic base region 12. The emitter layer 26 typically has a dopant polarity that is the same as the collector region which comprises in part the semiconductor substrate 10. Typically, the emitter layer 26 has a dopant concentration from about 10¹⁷ to about 10²¹ dopant atoms per cubic centimeter. Desirably, at least the portion of the emitter layer 26 in contact with the intrinsic base region 12 is epitaxially grown to provide a monocrystalline portion of the emitter layer 26. Alternatively, at least a remainder portion of the emitter layer 26, or potentially all of the emitter layer 26, is deposited as a polysilicon or polysilicon-germanium alloy material. Chemical vapor deposition methods are used as either epitaxial methods or non-epitaxial methods for forming the emitter layer 26. Silane or dichlorosilane are generally used as silicon source materials, although other silicon source materials may also be used. Typically, the emitter layer 26 has a thickness from about 1000 to about 3000 angstroms.

FIG. 8 shows a schematic cross-sectional diagram of a semiconductor structure comprising a bipolar transistor in accordance with an embodiment of the invention. The bipolar transistor comprises a vertical spacer layer 22′ for spacing an emitter layer 26 from an extrinsic base region 12′. The vertical spacer layer 22′ reduces capacitance effects between the emitter layer 26 and the extrinsic base region 12′. The vertical spacer layer 22′ is formed using a selective deposition method that allows the vertical spacer layer 22′ to be formed with minimal thermal exposure. Hence, the bipolar transistor that is illustrated in FIG. 8 may be fabricated with enhanced junction precision. The use of the selective deposition method for forming the vertical spacer layer 22′ also allows the bipolar transistor to be formed with reduced process complexity.

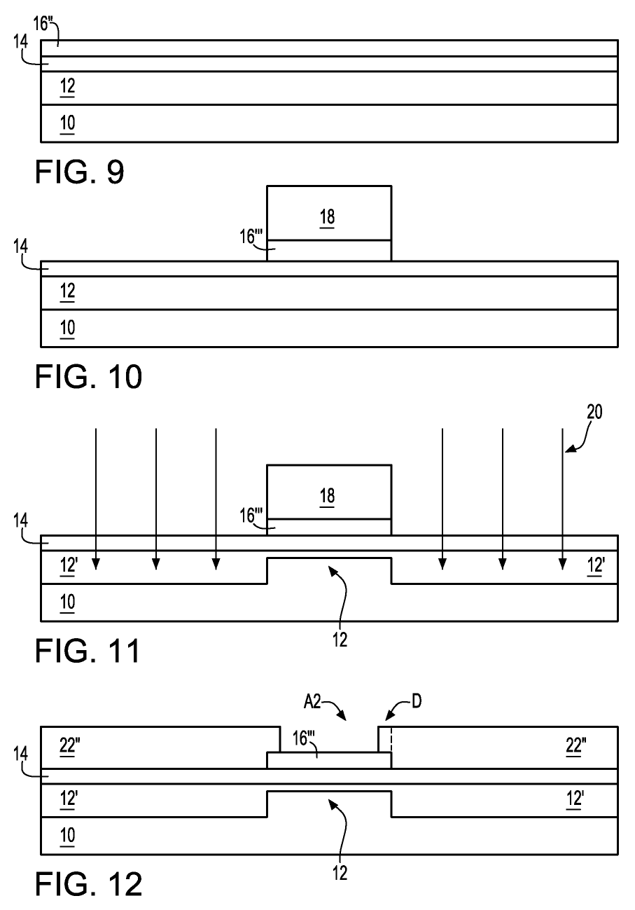

FIG. 9 to FIG. 15 show a series of schematic cross-sectional diagrams illustrating the results of progressive stages in fabricating a semiconductor structure comprising a bipolar transistor in accordance with another embodiment of the invention. This other embodiment of the invention comprises a second embodiment of the invention.

FIG. 9, FIG. 10 and FIG. 11 correspond generally with FIG. 1, FIG. 2 and FIG. 3, but with the exception that the hard mask layer 16″ or 16′″ is generally thinner in FIG. 9, FIG. 10 or FIG. 11 in comparison with the hard mask layer 16 or 16′ within FIG. 1, FIG. 2 or FIG. 3. Preferably, the hard mask layers 16″ and 16′″ within FIG. 9, FIG. 10 and FIG. 11 have a thickness from about 100 to about 1000 angstroms in comparison with the thickness disclosed above from about 500 to about 2000 angstroms for the hard mask layer 16 or 16′ that is illustrated in FIG. 1, FIG. 2 or FIG. 3.

As is illustrated in FIG. 12, as a result of the thinner hard mask layer 16′″ a pair of vertical spacer layers 22″ when selectively grown upon the screen dielectric layer 14 also grow laterally inward covering external portions of the hard mask layer 16′″. Those portions of the vertical spacer layers 22″ grow laterally inward for a distance D from about 100 to about 1000 angstroms. The vertical spacer layers 22″ also define an aperture A2, at the bottom of which is the hard mask layer 16′″. Otherwise, the methods and materials used for selectively depositing the vertical spacer layers 22″ that are illustrated in FIG. 12 are analogous, equivalent or identical to the methods and materials used for selectively depositing the vertical spacer layers 22 that are illustrated in FIG. 4 in the first embodiment.

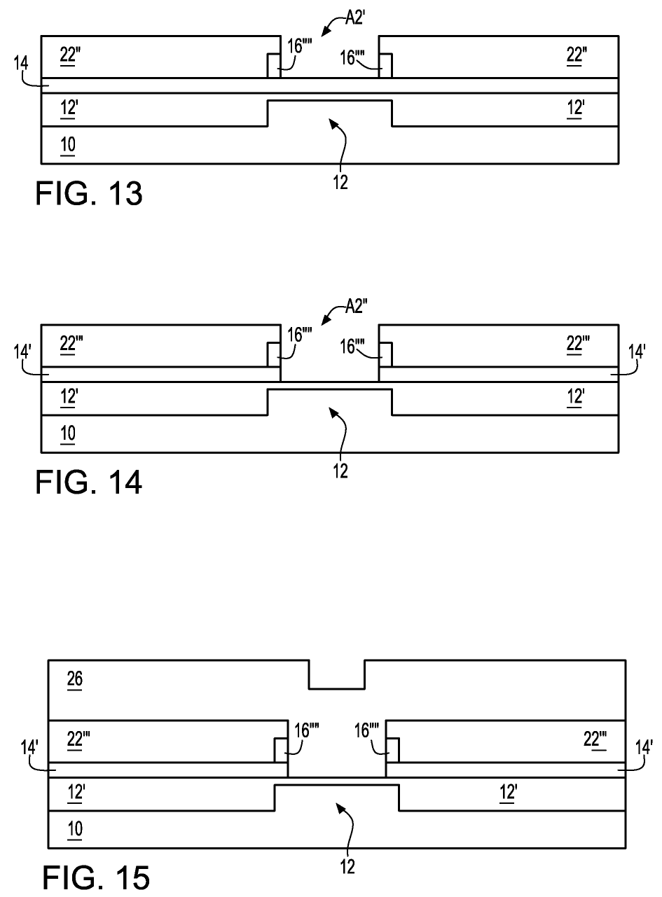

FIG. 13 shows the results of patterning the hard mask layer 16′″ to form hard mask derived intrinsic horizontal spacers 16″″ located embedded within and aligned within the sidewalls of an aperture A2′ defined in part by the vertical spacer layers 22″. Within the second embodiment, the hard mask derived intrinsic horizontal spacers 16″″ do not result from a separate deposition and etch back process step that is conventionally used for forming spacer layers. Rather, the intrinsic horizontal spacers 16″″ result from patterning the hard mask layer 16′″ while using the vertical spacer layers 22″ as a mask.

FIG. 14 shows the results of patterning the screen dielectric layer 14 to form the screen dielectric layer 14′ and simultaneously forming the aperture A2″ from the aperture A2′ that is illustrated in FIG. 13. As a result of the patterning, the vertical spacer layers 22″ are thinned (i.e., typically by a thickness from about 100 to about 500 angstroms) to form the vertical spacer layers 22′″. The processing for forming the semiconductor structure of FIG. 14 from the semiconductor structure of FIG. 13 within the second embodiment is analogous, equivalent or identical to the processing for forming the semiconductor structure of FIG. 7 from the semiconductor structure of FIG. 6 within the first embodiment.

FIG. 15 shows the results of forming the emitter layer 26 into the aperture A2″ and spanning over the pair of vertical spacer layers 22″″. The emitter layer 26 within the second embodiment is formed analogously, equivalently or identically to the emitter layer 26 within the first embodiment as illustrated in FIG. 8.

FIG. 15 shows a schematic cross-sectional diagram of a semiconductor structure comprising a bipolar transistor in accordance with a second embodiment of the invention. The bipolar transistor whose schematic cross-sectional diagram is illustrated in FIG. 15 also uses a selectively deposited vertical spacer layer 22′″ for purposes of spacing an emitter layer 26 from an intrinsic base region 12′. By using such a selectively deposited vertical spacer layer 22′″, a thermal budget for forming the bipolar transistor of FIG. 15 may (similarly with the first embodiment) be minimized. By virtue of the presence of such a minimized thermal budget, junctions, such as for the intrinsic base region 12, may be more precisely and uniformly controlled. The use of the selective vertical spacer layer 22′″ deposition also provides for reduced process complexity when fabricating a semiconductor structure comprising a bipolar transistor in accordance with either of the embodiments.

In addition, the second embodiment of the invention also uses overgrowth of a pair of selectively deposited vertical spacer layers 22′″ upon a generally thinner hard mask layer 16′″ such that hard mask derived horizontal spacer layers 16″″ may be formed embedded within and aligned within the sidewalls of an aperture A2″ defined in part by vertical spacer layers 22′″. The aperture A2″ exposes a surface region of the intrinsic base region 12.

The preferred embodiments of the invention are illustrative of the invention rather than limiting of the invention. Revisions and modifications may be made to methods, materials, structures and dimensions of a semiconductor structure including a bipolar transistor in accordance with the preferred embodiments of the invention, while still providing a semiconductor structure including a bipolar transistor in accordance with the invention, further in accordance with the accompanying claims.

What is claimed is:

1. A semiconductor structure comprising:
a semiconductor substrate comprising a collector region and an intrinsic base surface region located above and contacting the collector region;
a vertical spacer layer located above the semiconductor substrate, the vertical spacer layer having an aperture therein aligned above the intrinsic base surface region, the aperture having a horizontal spacer layer located embedded within and aligned within a sidewall thereof, and
an emitter layer located within the aperture and contacting the intrinsic base surface region.

2. The semiconductor structure of claim 1 wherein the semiconductor structure comprises an n-p-n bipolar transistor.

3. The semiconductor structure of claim 1 wherein the semiconductor structure comprises a p-n-p bipolar transistor.

4. The semiconductor structure of claim 1 wherein the intrinsic base surface region comprises a silicon-germanium alloy material.

5. The semiconductor structure of claim 1 wherein the vertical spacer layer comprises an oxide dielectric material and the horizontal spacer layer comprises a nitride dielectric material.

6. The semiconductor structure of claim 1 wherein a portion of the emitter layer also contacts a top surface of the vertical spacer layer.

7. The semiconductor structure of claim 6 wherein the portion of the emitter layer that contacts the top surface of the vertical spacer layer comprises a polycrystalline material and a portion of the emitter layer that contacts the intrinsic base region comprises a monocrystalline material.

8. A method for fabricating a semiconductor structure comprising:
implanting, while using an ion implantation mask layer located upon a screen dielectric layer which is located upon a semiconductor substrate having an intrinsic base surface region located beneath the ion implantation mask layer and a collector region located beneath the intrinsic base surface region, an extrinsic base region located laterally connected to the intrinsic base surface region;
selectively depositing a vertical spacer layer upon the screen dielectric layer adjoining the ion implantation mask layer after implanting the extrinsic base region;
stripping the ion implantation mask layer from the screen dielectric layer to yield an aperture within the vertical spacer layer, the screen dielectric layer being exposed at the base of the aperture;
removing the screen dielectric layer at the base of the aperture; and
forming an emitter layer into the aperture and contacting the intrinsic base surface region.

9. The method of claim 8 wherein the vertical spacer layer comprises an oxide material.

10. The method of claim 9 wherein the selective depositing uses a selectively deposited oxide dielectric material.

11. The method of claim 8 wherein the selective depositing uses a liquid phase deposition method.

12. The method of claim 11 wherein the liquid phase deposition method uses a supersaturated solution of hydrofluorosilicic acid.

13. The method of claim 8 wherein the forming the emitter layer forms the emitter layer as a monocrystalline material in contact with the intrinsic base region and a polycrystalline material in contact with the vertical spacer layer.

14. A method for fabricating a semiconductor structure comprising:
implanting, while using an ion implantation mask layer located upon a screen dielectric layer which is located upon a semiconductor substrate having an intrinsic base surface region located beneath the ion implantation mask layer and a collector region located beneath the intrinsic base surface region, an extrinsic base region located laterally connected to the intrinsic base surface region;
selectively depositing a vertical spacer layer upon the screen dielectric layer and encroaching upon the top surface of the adjoining the ion implantation mask layer after implanting the extrinsic base region;
etching the ion implantation mask layer from the screen dielectric layer to yield an aperture within the vertical spacer layer, the screen dielectric layer being exposed at the base of the aperture, and a horizontal spacer layer being located embedded within and aligned with a sidewall of the aperture;
removing the screen dielectric layer at the base of the aperture; and
forming an emitter layer into the aperture and contacting the intrinsic base surface region.

15. The method of claim 14 wherein the vertical spacer layer comprises an oxide material.

16. The method of claim 14 wherein the selective deposition uses a selectively deposited oxide dielectric material.

17. The method of claim 14 wherein the selectively depositing uses a liquid phase deposition method.

18. The method of claim 17 wherein the liquid phase deposition method uses a supersaturated solution of hydrofluorosilicic acid.

19. The method of claim 14 wherein the forming the emitter layer forms the emitter layer as a monocrystalline material in contact with the intrinsic base region and a polycrystalline material in contact with the vertical spacer layer.

20. The method of claim 14 wherein the forming the emitter layer forms the emitter layer as a polycrystalline material in contact with both the intrinsic base region and the vertical spacer layer.
